(19) United States
(12) Patent Application Publication
(10) Pub. No.: US 2019/0014696 A1
(43) Pub. Date: Jan. 10, 2019

(54) ELECTRONIC DEVICE

(71) Applicant: LG ELECTRONICS INC., Seoul (KR)

(72) Inventors: Hyengcheul CHOI, Seoul (KR); Jihwan KIM, Seoul (KR); Taehoon KIM, Seoul (KR); Ansun HYUN, Seoul (KR)

(73) Assignee: LG ELECTRONICS INC., Seoul (KR)

(21) Appl. No.: 15/804,225

(22) Filed: Nov. 6, 2017

(30) Foreign Application Priority Data
Jul. 10, 2017 (KR) 10-2017-0087256

(51) Int. Cl. H05K 9/00

(52) U.S. Cl. CPC H05K 9/0037; H05K 9/0075; H05K 9/0052; H05K 9/0081

(57) ABSTRACT

The present invention relates to an electronic device, including a body including an inner frame, a circuit board disposed inside the body to transmit a signal, an electronic component disposed on the circuit board, and a shield can disposed between the circuit board and the inner frame, and covering the electronic component such that a current induced from the electronic component flows toward the circuit board, wherein the shield can includes a base portion including a first region fixed to the circuit board, and a second region covering the electronic component, and at least one magnet portion overlapping the second region of the base portion, and forming a magnetic field in a direction from inside to outside of the base portion so as to disperse the current on the base portion.

### CROSS-REFERENCE TO RELATED APPLICATION

Pursuant to 35 U.S.C. § 119(a), this application claims the benefit of earlier filing date and right of priority to Korean Patent Application No. 10-2017-0087256, filed on Jul. 10, 2017, the contents of which are hereby incorporated by reference herein in its entirety.

### FIELD OF THE INVENTION

The present invention relates to an electronic device having a circuit board on which a shield can is mounted.

### BACKGROUND OF THE INVENTION

Electronic devices may be divided into mobile/portable terminals and stationary terminals according to mobility. Also, the mobile terminals may be classified into handheld types and vehicle mount types according to whether or not a user can directly carry.

The terminal has various functions according to development of technologies. For example, a mobile terminal can be allowed to capture still images or moving images, play music or video files, play games, receive broadcast and the like, so as to be implemented as an integrated multimedia player. Efforts are ongoing to support and increase the functionality of terminals. Such efforts include software improvements, as well as changes and improvements in the structural components.

In recent years, as the terminal becomes simple in design and thin in thickness, a thickness of a shield can disposed above electronic components to shield electromagnetic waves has to be reduced. However, when the thickness of the shield can is reduced, the electromagnetic waves reach only a specific region adjacent to the shield can, and accordingly a region where a current flows is limited to the specific region.

Further, when a high frequency signal having a straight-running property flows due to the electronic components, the current induced by the electromagnetic waves reaches only a near partial region of the shield can, which may prevent the radiated electromagnetic waves from efficiently being discharged to the ground, or cause noise to be coupled to another line within the shield can. Or, when the induced current fails to be transferred to the ground through the shield can, a problem arises that the shield can structure itself becomes an Electro Magnetic Interference (EMI) radiator.

### SUMMARY OF THE INVENTION

An aspect of the present invention is to solve the above-mentioned problems and other drawbacks, namely, to provide an electronic device having a shield can for effectively blocking electromagnetic waves in an electronic device that is slim and provided with electronic components generating high-frequency waves.

To achieve these and other advantages and in accordance with the purpose of this specification, as embodied and broadly described herein, there is provided an electronic device, including a body provided with an inner frame, a circuit board disposed inside the body to transmit a signal, an electronic component disposed on the circuit board, and a shield can disposed between the circuit board and the inner frame, and covering the electronic component such that a current induced from the electronic component flows toward the circuit board, wherein the shield can includes a base portion including a first region fixed to the circuit board, and a second region covering the electronic component, and at least one magnet portion overlapping the second region of the base portion, and forming a magnetic field in a direction from inside to outside of the base portion so as to disperse the current on the base portion.

In one embodiment disclosed herein, the at least one magnet portion may have a closed loop shape with a central region open, and a forming direction of the magnetic field and a flowing direction of the current may intersect with each other. This may allow an AC current to be dispersed to an outer region of the shield can.

In one embodiment disclosed herein, a thermal pad may be provided in manner of being brought into contact with an outer surface of the second region of the shield can to transfer heat, and the at least one magnet portion may be provided on the thermal pad or on an inner surface of the second region, thereby implementing a shield can having a heat dissipating structure.

According to the present invention, an induced current flowing in the shield can be dispersed from a central region to an outer region along a direction of a magnetic field of the magnet portion.

Therefore, even when a thickness of the shield can itself decreases due to slimming of the electronic device, the current can be dispersed. Further, even when an electronic component generating high-frequency electromagnetic waves having a straight-running property is disposed, the induced current can be dispersed without being concentrated on a specific region. Thus, the induced current can be effectively grounded.

### BRIEF DESCRIPTION OF THE DRAWINGS

FIG. 1A is a block diagram of a mobile terminal in accordance with the present invention.

FIGS. 1B and 1C are views of a mobile terminal according to one embodiment of the present invention, viewed from different directions.

FIG. 2 is an exploded view of FIG. 10.

FIGS. 3A and 3B are views illustrating a structure of a first shield can.

FIG. 3C is a conceptual view illustrating a characteristic in which currents flowing in a shield can are dispersed by a magnet portion.

FIG. 3D is a conceptual view illustrating a structure in which a heat dissipating structure is disposed in a shield can in accordance with one embodiment.

FIG. 3E is a conceptual view illustrating a shield can having an adhesive member for attaching a magnet portion.

FIGS. 4A and 4B are conceptual views illustrating a second shield can in accordance with another embodiment.

FIG. 4C is a conceptual view illustrating a structure in which a magnet portion is fixed by an adhesive member.

FIGS. 5A and 5B are conceptual views illustrating a structure of a third shield can in accordance with another embodiment of the present invention.

FIGS. 6A and 6B are conceptual views illustrating a fourth shield can in accordance with another embodiment of the present invention.

FIGS. 7A and 7B are conceptual views illustrating a fifth shield can in accordance with one embodiment of the present invention.

FIG. 8 is a conceptual view illustrating a structure of a sixth shield can in accordance with another embodiment of the present invention.

FIGS. 9A to 9C are conceptual views illustrating an arrangement structure of a heat dissipating structure and a shield can.

FIG. 10 is a conceptual view illustrating a structure of a ninth shield can in accordance with another embodiment.

FIG. 11 is a conceptual view illustrating a structure of a shield can implemented by an inner frame in accordance with another embodiment.

### DETAILED DESCRIPTION OF THE INVENTION

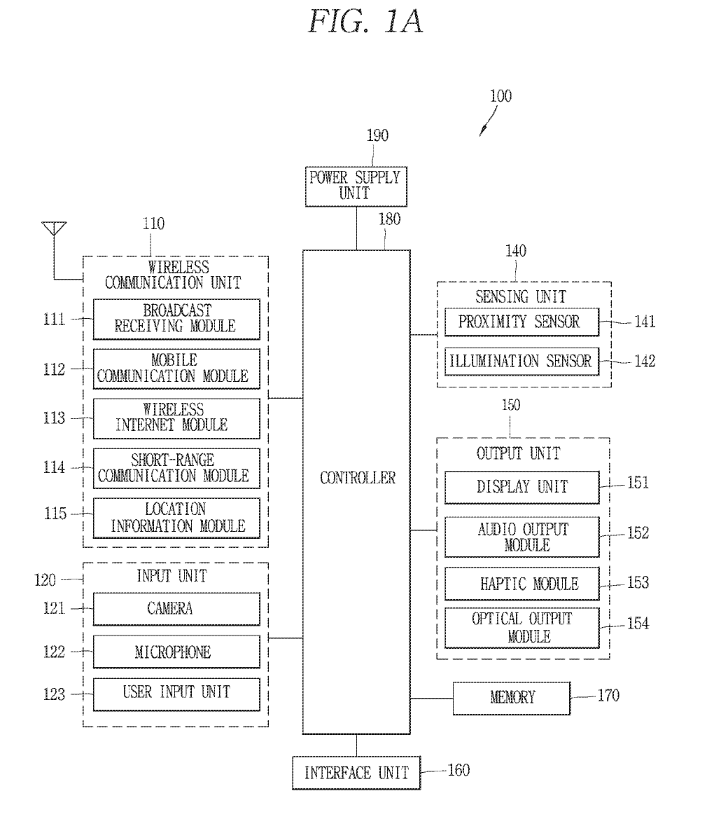

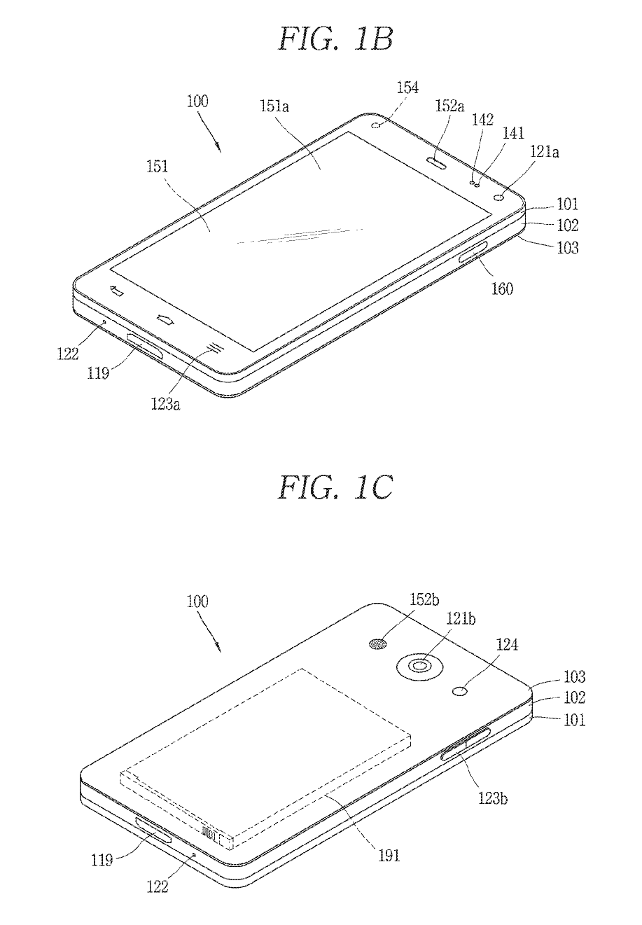

FIG. 1A is a block diagram of a mobile terminal in accordance with the present disclosure.

The mobile terminal 100 may be shown having components such as a wireless communication unit 110, an input unit 120, a sensing unit 140, an output unit 150, an interface unit 160, a memory 170, a controller 180, and a power supply unit 190. FIG. 1 shows the electronic device 100 having various components, but it may be understood that implementing all of the illustrated components is not a requirement. Greater or fewer components may alternatively be implemented.

In more detail, among others, the wireless communication unit 110 may typically include one or more modules which permit communications such as wireless communications between the electronic device 100 and a wireless communication system, communications between the electronic device 100 and another mobile terminal, or communications between the electronic device 100 and an external server. Further, the wireless communication unit 110 may typically include one or more modules which connect the mobile electronic device 100 to one or more networks.

The wireless communication unit 110 may include one or more of a broadcast receiving module 111, a mobile communication module 112, a wireless Internet module 113, a short-range communication module 114, and a location information module 115.

The input unit 120 may include a camera 121 or an image input unit for obtaining images or video, a microphone 122, which is one type of audio input device for inputting an audio signal, and a user input unit 123 (for example, a touch key, a mechanical key, and the like) for allowing a user to input information. Data (for example, audio, video, image, and the like) may be obtained by the input unit 120 and may be analyzed and processed according to user commands.

The sensing unit 140 may typically be implemented using one or more sensors configured to sense internal information of the mobile terminal, the surrounding environment of the mobile terminal, user information, and the like. For example, the sensing unit 140 may include at least one of a proximity sensor 141, an illumination sensor 142, a touch sensor, an acceleration sensor, a magnetic sensor, a G-sensor, a gyroscope sensor, a motion sensor, an RGB sensor, an infrared (IR) sensor, a finger scan sensor, a ultrasonic sensor, an optical sensor (for example, camera 121), a microphone 122, a battery gauge, an environment sensor (for example, a barometer, a hygrometer, a thermometer, a radiation detection sensor, a thermal sensor, and a gas sensor, among others), and a chemical sensor (for example, an electronic nose, a health care sensor, a biometric sensor, and the like). The electronic device disclosed herein may be configured to utilize information obtained from one or more sensors of the sensing unit 140, and combinations thereof.

The output unit 150 may typically be configured to output various types of information, such as audio, video, tactile output, and the like. The output unit 150 may be shown having at least one of a display unit 151, an audio output module 152, a haptic module 153, and an optical output module 154. The display unit 151 may have an inter-layered structure or an integrated structure with a touch sensor in order to implement a touch screen. The touch screen may function as the user input unit 123 which provides an input interface between the electronic device 100 and the user and simultaneously provide an output interface between the electronic device 100 and a user.

The interface unit 160 serves as an interface with various types of external devices that are coupled to the electronic device 100. The interface unit 160, for example, may include any of wired or wireless ports, external power supply ports, wired or wireless data ports, memory card ports, ports for connecting a device having an identification module, audio input/output (I/O) ports, video I/O ports, earphone ports, and the like. In some cases, the electronic device 100 may perform assorted control functions associated with a connected external device, in response to the external device being connected to the interface unit 160.

The memory 170 is typically implemented to store data to support various functions or features of the electronic device 100. For instance, the memory 170 may be configured to store application programs executed in the electronic device 100, data or instructions for operations of the electronic device 100, and the like. Some of these application programs may be downloaded from an external server via wireless communication. Other application programs may be installed within the electronic device 100 at time of manufacturing or shipping, which is typically the case for basic functions of the electronic device 100 (for example, receiving a call, placing a call, receiving a message, sending a message, and the like). It is common for application programs to be stored in the memory 170, installed in the electronic device 100, and executed by the controller 180 to perform an operation (or function) for the electronic device 100.

The controller 180 typically functions to control an overall operation of the electronic device 100, in addition to the operations associated with the application programs. The controller 180 may provide or process information or functions appropriate for a user by processing signals, data, information and the like, which are input or output by the aforementioned various components, or activating application programs stored in the memory 170.

Also, the controller 180 may control at least some of the components illustrated in FIG. 1A, to execute an application program that have been stored in the memory 170. In addition, the controller 180 may control at least two of those components included in the electronic device to activate the application program.

The power supply unit 190 may be configured to receive external power or provide internal power in order to supply appropriate power required for operating elements and components included in the electronic device 100. The power supply unit 190 may include a battery, and the battery may be configured as an embedded battery or a detachable battery.

At least part of the components may cooperatively operate to implement an operation, a control or a control method of the electronic device 100 according to various embodiments disclosed herein. Also, the operation, the control or the control method of the electronic device 100 may be implemented on electronic device by an activation of at least one application program stored in the memory 170.

Hereinafter, description will be given in more detail of the aforementioned components with reference to FIG. 1A, prior to describing various embodiments implemented through the electronic device 100.

First, regarding the wireless communication unit 110, the broadcast receiving module 111 is typically configured to receive a broadcast signal and/or broadcast associated information from an external broadcast managing entity via a broadcast channel. The broadcast channel may include a satellite channel, a terrestrial channel, or both. In some embodiments, two or more broadcast receiving modules 111 may be utilized to facilitate simultaneous reception of two or more broadcast channels, or to support switching among broadcast channels.

The mobile communication module 112 may transmit and/or receive wireless signals to and from one or more network entities. Typical examples of a network entity include a base station, an external mobile terminal, a server, and the like. Such network entities form part of a mobile communication network, which is constructed according to technical standards or communication methods for mobile communications (for example, Global System for Mobile Communication (GSM), Code Division Multi Access (CDMA), CDMA2000 (Code Division Multi Access 2000), EV-DO (Enhanced Voice-Data Optimized or Enhanced Voice-Data Only), Wideband CDMA (WCDMA), High Speed Downlink Packet access (HSDPA), HSUPA (High Speed Uplink Packet Access), Long Term Evolution (LTE), LTE-A (Long Term Evolution-Advanced), and the like).

The wireless signal may include various types of data depending on a voice call signal, a video call signal, or a text/multimedia message transmission/reception.

The wireless Internet module 113 refers to a module for wireless Internet access. This module may be internally or externally coupled to the electronic device 100. The wireless Internet module 113 may transmit and/or receive wireless signals via communication networks according to wireless Internet technologies.

Examples of such wireless Internet access include Wireless LAN (WLAN), Wireless Fidelity (Wi-Fi), Wi-Fi Direct, Digital Living Network Alliance (DLNA), Wireless Broadband (WiBro), Worldwide Interoperability for Microwave Access (WiMAX), High Speed Downlink Packet Access (HSDPA), High Speed Uplink Packet Access (HSUPA), Long Term Evolution (LTE), LTE-advanced (LTE-A) and the like. The wireless Internet module 113 may transmit/receive data according to one or more of such wireless Internet technologies, and other Internet technologies as well.

When the wireless Internet access is implemented according to, for example, WiBro, HSDPA, HSUPA, GSM, CDMA, WCDMA, LTE, LTE-A and the like, as part of a mobile communication network, the wireless Internet module 113 performs such wireless Internet access. As such, the Internet module 113 may cooperate with, or function as, the mobile communication module 112.

The short-range communication module 114 is configured to facilitate short-range communications. Suitable technologies for implementing such short-range communications include BLUETOOTH™, Radio Frequency IDentification (RFID), Infrared Data Association (IrDA), Ultra-WideBand (UWB), ZigBee, Near Field Communication (NFC), Wireless-Fidelity (Wi-Fi), Wi-Fi Direct, Wireless USB (Wireless Universal Serial Bus), and the like. The short-range communication module 114 in general supports wireless communications between the electronic device 100 and a wireless communication system, communications between the electronic device 100 and another electronic device, or communications between the electronic device and a network where another electronic device (or an external server) is located, via wireless area networks. One example of the wireless area networks is a wireless personal area networks.

Here, another electronic device may be a wearable device, for example, a smart watch, a smart glass or a head mounted display (HMD), which is able to exchange data with the electronic device 100 (or otherwise cooperate with the electronic device 100). The short-range communication module 114 may sense or recognize the wearable device, and permit communication between the wearable device and the electronic device 100. In addition, when the sensed wearable device is a device which is authenticated to communicate with the electronic device 100, the controller 180, for example, may cause transmission of at least part of data processed in the electronic device 100 to the wearable device via the short-range communication module 114. Hence, a user of the wearable device may use the data processed in the electronic device 100 on the wearable device. For example, when a call is received in the electronic device 100, the user may answer the call using the wearable device. Also, when a message is received in the electronic device 100, the user can check the received message using the wearable device.

The location information module 115 is generally configured to detect, calculate, derive or otherwise identify a position (or current position) of the electronic device. As an example, the location information module 115 includes a Global Position System (GPS) module, a Wi-Fi module, or both. For example, when the electronic device uses a GPS module, a position of the electronic device may be acquired using a signal sent from a GPS satellite. As another example, when the electronic device uses the Wi-Fi module, a position of the electronic device may be acquired based on information related to a wireless access point (AP) which transmits or receives a wireless signal to or from the Wi-Fi module. If desired, the location information module 115 may alternatively or additionally perform a function of any of the other modules of the wireless communication unit 110 to obtain data related to the position of the electronic device 100. The location information module 115 is a module used for acquiring the position (or the current position) of the electronic device 100, and may not be limited to a module for directly calculating or acquiring the position of the electronic device.

Next, the input unit 120 is configured to permit various types of inputs to the electronic device 100. Examples of such inputs include image information (or signal), audio information (or signal), data or various information input by a user, and may be provided with one or a plurality of cameras 121. Such cameras 121 may process image frames of still pictures or video obtained by image sensors in a video or image capture mode. The processed image frames can be displayed on the display unit 151 or stored in memory 170. Meanwhile, the cameras 121 may be arranged in a matrix configuration to permit a plurality of images having various angles or focal points to be input to the electronic device 100. Also, the cameras 121 may be located in a stereoscopic arrangement to acquire left and right images for implementing a stereoscopic image.

The microphone 122 processes an external audio signal into electric audio (sound) data. The processed audio data may be processed in various manners according to a function being executed in the electronic device 100. If desired, the microphone 122 may include assorted noise removing algorithms to remove unwanted noise generated in the course of receiving the external audio signal.

The user input unit 123 is a component that permits input by a user. Such user input may enable the controller 180 to control operation of the electronic device 100. The user input unit 123 may include a mechanical input element (or a mechanical key, for example, a button located on a front and/or rear surface or a side surface of the electronic device 100, a dome switch, a jog wheel, a jog switch, and the like), or a touch-sensitive input element, among others. As one example, the touch-sensitive input element may be a virtual key, a soft key or a visual key, which is displayed on a touch screen through software processing, or a touch key which is located on the mobile terminal at a location that is other than the touch screen. On the other hand, the virtual key or the visual key may be displayed on the touch screen in various shapes, for example, graphic, text, icon, video, or a combination thereof.

The sensing unit 140 is generally configured to sense one or more of internal information of the electronic device, surrounding environment information of the electronic device, user information, or the like, and generates a corresponding sensing signal. The controller 180 generally cooperates with the sending unit 140 to control operation of the electronic device 100 or execute data processing, a function or an operation associated with an application program installed in the electronic device 100 based on the sensing signal. The sensing unit 140 may be implemented using any of a variety of sensors, some of which will now be described in more detail.

The proximity sensor 141 refers to a sensor to sense presence or absence of an object approaching a surface, or an object located near a surface, by using an electromagnetic field, infrared rays, or the like without a mechanical contact. The proximity sensor 141 may be arranged at an inner region of the electronic device covered by the touch screen, or near the touch screen.

The proximity sensor 141, for example, may include any of a transmissive type photoelectric sensor, a direct reflective type photoelectric sensor, a mirror reflective type photoelectric sensor, a high-frequency oscillation proximity sensor, a capacitance type proximity sensor, a magnetic type proximity sensor, an infrared rays proximity sensor, and the like. When the touch screen is implemented as a capacitance type, the proximity sensor 141 can sense proximity of a pointer relative to the touch screen by changes of an electromagnetic field, which is responsive to an approach of an object with conductivity. In this case, the touch screen (touch sensor) may also be categorized as a proximity sensor.

The term “proximity touch” will often be referred to herein to denote the scenario in which a pointer is positioned to be proximate to the touch screen without contacting the touch screen. The term “contact touch” will often be referred to herein to denote the scenario in which a pointer makes physical contact with the touch screen. For the position corresponding to the proximity touch of the pointer relative to the touch screen, such position will correspond to a position where the pointer is perpendicular to the touch screen. The proximity sensor 141 may sense proximity touch, and proximity touch patterns (for example, distance, direction, speed, time, position, moving status, and the like). In general, the controller 180 may process data corresponding to proximity touches and proximity touch patterns sensed by the proximity sensor 141, and cause output of visual information on the touch screen. In addition, the controller 180 may control the electronic device 100 to execute different operations or process different data (or information) according to whether a touch with respect to a point on the touch screen is either a proximity touch or a contact touch.

A touch sensor can sense a touch (or a touch input) applied to the touch screen, such as display unit 151, using any of a variety of touch methods. Examples of such touch methods include a resistive type, a capacitive type, an infrared type, and a magnetic field type, among others.

As one example, the touch sensor may be configured to convert changes of pressure applied to a specific part of the display unit 151, or convert capacitance occurring at a specific part of the touch screen, into electric input signals. The touch sensor may also be configured to sense not only a touched position and a touched area, but also touch pressure and/or touch capacitance. A touch object is generally used to apply a touch input to the touch sensor. Examples of typical touch objects include a finger, a touch pen, a stylus pen, a pointer, or the like.

When a touch input is sensed by a touch sensor, corresponding signals may be transmitted to a touch controller. The touch controller may process the received signals, and then transmit corresponding data to the controller 180. Accordingly, the controller 180 may sense which region of the display unit 151 has been touched. Here, the touch controller may be a component separate from the controller 180, the controller 180, and combinations thereof.

Meanwhile, the controller 180 may execute the same or different controls according to a type of touch object that touches the touch screen or a touch key provided in addition to the touch screen. Whether to execute the same or different control according to a type of an object which provides a touch input may be decided based on a current operating state of the electronic device 100 or a currently executed application program, for example.

The touch sensor and the proximity sensor may be implemented individually, or in combination, to sense various types of touches. Such touches includes a short (or tap) touch, a long touch, a multi-touch, a drag touch, a flick touch, a pinch-in touch, a pinch-out touch, a swipe touch, a hovering touch, and the like.

If desired, an ultrasonic sensor may be implemented to recognize location information relating to a touch object using ultrasonic waves. The controller 180, for example, may calculate a position of a wave generation source based on information sensed by an illumination sensor and a plurality of ultrasonic sensors. Since light is much faster than ultrasonic waves, the time for which the light reaches the optical sensor is much shorter than the time for which the ultrasonic wave reaches the ultrasonic sensor. The position of the wave generation source may be calculated using this fact. For instance, the position of the wave generation source may be calculated using the time difference from the time that the ultrasonic wave reaches the sensor based on the light as a reference signal.

The camera 121, which has been depicted as a component of the input unit 120, typically includes at least one a camera sensor (CCD, CMOS etc.), a photo sensor (or image sensors), and a laser sensor.

Implementing the camera 121 with a laser sensor may allow detection of a touch of a physical object with respect to a 3D stereoscopic image. The photo sensor may be laminated on, or overlapped with, the display device. The photo sensor may be configured to scan movement of the object in vicinity of the touch screen. In more detail, the photo sensor may include photo diodes and transistors (TRs) at rows and columns to scan content received at the photo sensor using an electrical signal which changes according to the quantity of applied light. Namely, the photo sensor may calculate the coordinates of the physical object according to variation of light to thus obtain location information of the physical object.

The display unit 151 is generally configured to output information processed in the electronic device 100. For example, the display unit 151 may display execution screen information of an application program executing at the electronic device 100 or user interface (UI) and graphic user interface (GUI) information in response to the execution screen information.

Also, the display unit 151 may be implemented as a stereoscopic display unit for displaying stereoscopic images.

A typical stereoscopic display unit may employ a stereoscopic display scheme such as a stereoscopic scheme (a glass scheme), an auto-stereoscopic scheme (glassless scheme), a projection scheme (holographic scheme), or the like.

The audio output module 152 may receive audio data from the wireless communication unit 110 or output audio data stored in the memory 170 during modes such as a signal reception mode, a call mode, a record mode, a voice recognition mode, a broadcast reception mode, and the like. The audio output module 152 may provide audible output related to a particular function (e.g., a call signal reception sound, a message reception sound, etc.) performed by the electronic device 100. The audio output module 152 may also be implemented as a receiver, a speaker, a buzzer, or the like.

A haptic module 153 can be configured to generate various tactile effects that a user feels, perceives, or otherwise experiences. A typical example of a tactile effect generated by the haptic module 153 is vibration. The strength, pattern and the like of the vibration generated by the haptic module 153 can be controlled by user selection or setting by the controller. For example, the haptic module 153 may output different vibrations in a combining manner or a sequential manner.

Besides vibration, the haptic module 153 can generate various other tactile effects, including an effect by stimulation such as a pin arrangement vertically moving to contact skin, a spray force or suction force of air through a jet orifice or a suction opening, a touch to the skin, a contact of an electrode, electrostatic force, an effect by reproducing the sense of cold and warmth using an element that can absorb or generate heat, and the like.

The haptic module 153 can also be implemented to allow the user to feel a tactile effect through a muscle sensation such as the user's fingers or arm, as well as transferring the tactile effect through direct contact. Two or more haptic modules 153 may be provided according to the particular configuration of the electronic device 100.

An optical output module 154 may output a signal for indicating an event generation using light of a light source. Examples of events generated in the mobile terminal 100 may include message reception, call signal reception, a missed call, an alarm, a schedule notice, an email reception, information reception through an application, and the like.

A signal output by the optical output module 154 may be implemented in such a manner that the electronic device 100 emits monochromatic light or light with a plurality of colors to a front or rear surface. The signal output may be terminated as the electronic device senses that a user has checked the generated event, for example.

The interface unit 160 serves as an interface for external devices to be connected with the electronic device 100. For example, the interface unit 160 can receive data transmitted from an external device, receive power to transfer to elements and components within the electronic device 100, or transmit internal data of the electronic device 100 to such external device. The interface unit 160 may include wired or wireless headset ports, external power supply ports, wired or wireless data ports, memory card ports, ports for connecting a device having an identification module, audio input/output (I/O) ports, video I/O ports, earphone ports, or the like.

The identification module may be a chip that stores various information for authenticating authority of using the electronic device 100 and may include a user identity module (UIM), a subscriber identity module (SIM), a universal subscriber identity module (USIM), and the like. In addition, the device having the identification module (also referred to herein as an “identifying device”) may take the form of a smart card. Accordingly, the identifying device can be connected with the electronic device 100 via the interface unit 160.

When the electronic device 100 is connected with an external cradle, the interface unit 160 can serve as a passage to allow power from the cradle to be supplied to the electronic device 100 or may serve as a passage to allow various command signals input by the user from the cradle to be transferred to the electronic device therethrough. Various command signals or power input from the cradle may operate as signals for recognizing that the electronic device is properly mounted on the cradle.

The memory 170 can store programs to support operations of the controller 180 and store input/output data (for example, phonebook, messages, still images, videos, etc.). The memory 170 may store data related to various patterns of vibrations and audio which are output in response to touch inputs on the touch screen.

The memory 170 may include one or more types of storage mediums including a flash memory type, a hard disk type, a solid state disk (SSD) type, a silicon disk drive (SDD) type, a multimedia card micro type, a card-type memory (e.g., SD or DX memory, etc), a Random Access Memory (RAM), a Static Random Access Memory (SRAM), a Read-Only Memory (ROM), an Electrically Erasable Programmable Read-Only Memory (EEPROM), a Programmable Read-Only memory (PROM), a magnetic memory, a magnetic disk, an optical disk, and the like. The electronic device 100 may also be operated in relation to a network storage device that performs the storage function of the memory 170 over a network, such as the Internet.

The controller 180 may typically control operations relating to application programs and the general operations of the electronic device 100. For example, the controller 180 may set or release a lock state for restricting a user from inputting a control command with respect to applications when a status of the electronic device meets a preset condition.

The controller 180 can also perform the controlling and processing associated with voice calls, data communications, video calls, and the like, or perform pattern recognition processing to recognize a handwriting input or a picture drawing input performed on the touch screen as characters or images, respectively. In addition, the controller 180 may control one or a combination of those components in order to implement various exemplary embodiments disclosed herein.

The power supply unit 190 receives external power or provide internal power and supply the appropriate power required for operating respective elements and components included in the electronic device 100 under the control of the controller 180. The power supply unit 190 may include a battery, which is typically rechargeable or be detachably coupled to the terminal body for charging.

The power supply unit 190 may include a connection port. The connection port may be configured as one example of the interface unit 160 to which an external charger for supplying power to recharge the battery is electrically connected.

As another example, the power supply unit 190 may be configured to recharge the battery in a wireless manner without use of the connection port. In this example, the power supply unit 190 can receive power, transferred from an external wireless power transmitter, using at least one of an inductive coupling method which is based on magnetic induction or a magnetic resonance coupling method which is based on electromagnetic resonance.

Various embodiments described herein may be implemented in a computer-readable medium, a machine-readable medium, or similar medium using, for example, software, hardware, or any combination thereof.

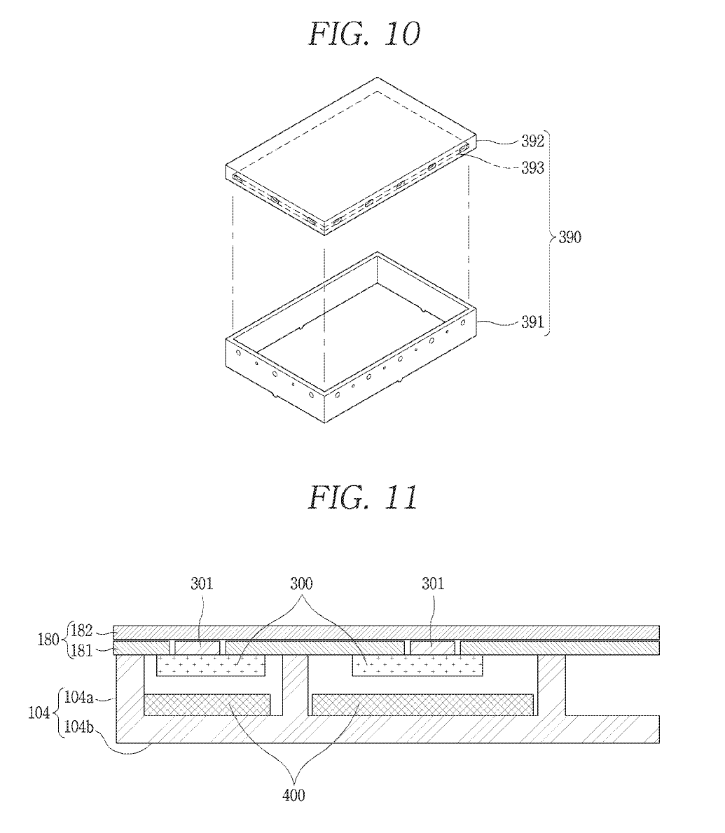

Hereinafter, description will be given of a structure of the electronic device 100 according to the one embodiment of the present invention illustrated in FIG. 1 A or a terminal having those components, with reference to FIG. 10.

Referring to FIGS. 1B and 10, the disclosed electronic device 100 includes a bar-like terminal body. However, the mobile terminal 100 may alternatively be implemented in any of a variety of different configurations. Examples of such configurations include watch type, clip-type, glasses-type, or a folder-type, flip-type, slide-type, swing-type, and swivel-type in which two and more bodies are combined with each other in a relatively movable manner, and combinations thereof. Discussion herein will often relate to a particular type of electronic device. However, such teachings with regard to a particular type of electronic device will generally be applied to other types of electronic devices as well.

Here, considering the electronic device 100 as at least one assembly, the terminal body may be understood as a conception referring to the assembly.

The electronic device 100 will generally include a case (for example, frame, housing, cover, and the like) forming the appearance of the terminal. In this embodiment, the case is formed using a front case 101 and a rear case 102. Various electronic components are interposed into a space formed between the front case 101 and the rear case 102. At least one middle case may be additionally positioned between the front case 101 and the rear case 102.

The display unit 151 is shown located on the front side of the terminal body to output information. As illustrated, a window 151a of the display unit 151 may be mounted to the front case 101 to form the front surface of the terminal body together with the front case 101.

In some embodiments, electronic components may also be mounted to the rear case 102. Examples of such electronic components include a detachable battery 191, an identification module, a memory card, and the like. In this case, a rear cover 103 is shown covering the electronic components, and this cover may be detachably coupled to the rear case 102. Therefore, when the rear cover 300 is detached from the rear case 102, the electronic components mounted on the rear case 102 are exposed to the outside.

As illustrated, when the rear cover 300 is coupled to the rear case 102, a side surface of the rear case 102 may partially be exposed. In some cases, upon the coupling, the rear case 102 may also be completely shielded by the rear cover 300. Meanwhile, the rear cover 300 may include an opening for externally exposing a camera 121b or an audio output module 152b.

The cases 101, 102, 103 may be formed by injection-molding synthetic resin or may be formed of a metal, for example, stainless steel (STS), aluminum (Al), titanium (Ti), or the like.

As an alternative to the example in which the plurality of cases form an inner space for accommodating components, the electronic device 100 may be configured such that one case forms the inner space. In this case, an electronic device 100 having a uni-body is formed in such a manner that synthetic resin or metal extends from a side surface to a rear surface.

Meanwhile, the electronic device 100 may include a waterproofing unit (not shown) for preventing introduction of water into the terminal body. For example, the waterproofing unit may include a waterproofing member which is located between the window 151a and the front case 101, between the front case 101 and the rear case 102, or between the rear case 102 and the rear cover 300, to hermetically seal an inner space when those cases are coupled.

The electronic device 100 may include a display unit 151, first and second audio output module 152a and 152b, a proximity sensor 141, an illumination sensor 142, an optical output module 154, first and second cameras 121a and 121b, first and second manipulation units 123a and 123b, a microphone 122, an interface unit 160, and the like.

Hereinafter, as illustrated in FIGS. 1B and 1C, description will be given of the exemplary electronic device 100 in which the front surface of the terminal body is shown having the display unit 151, the first audio output module 152a, the proximity sensor 141, the illumination sensor 142, the optical output module 154, the first camera 121a, and the first manipulation unit 123a, the side surface of the terminal body is shown having the second manipulation unit 123b, the microphone 122, and the interface unit 160, and the rear surface of the terminal body is shown having the second audio output module 152b and the second camera 121b.

However, those components may not be limited to the arrangement. Some components may be omitted or rearranged or located on different surfaces. For example, the first manipulation unit 123a may be located on another surface of the terminal body, and the second audio output module 152b may be located on the side surface of the terminal body other than the rear surface of the terminal body.

The display unit 151 is generally configured to output information processed in the electronic device 100. For example, the display unit 151 may display execution screen information of an application program executed on the electronic device 100 or user interface (UI) and graphic user interface (GUI) information in response to the execution screen information.

The display unit 151 may be implemented using one or more suitable display devices. Examples of such suitable display devices include a liquid crystal display (LCD), a thin film transistor-liquid crystal display (TFT-LCD), an organic light emitting diode (OLED), a flexible display, a 3-dimensional (3D) display, an e-ink display, and combinations thereof.

The display unit 151 may be implemented using two display devices, according to the configuration type thereof. For instance, a plurality of the display units 151 may be arranged on one side, either spaced apart from each other, or these devices may be integrated, or these devices may be arranged on different surfaces.

The display unit 151 may include a touch sensor that senses a touch with respect to the display unit 151 so as to receive a control command in a touch manner. Accordingly, when a touch is applied to the display unit 151, the touch sensor may sense the touch, and a controller 180 may generate a control command corresponding to the touch. Contents input in the touch manner may be characters, numbers, instructions in various modes, or a menu item that can be designated.

On the other hand, the touch sensor may be configured in a form of a film having a touch pattern and disposed between a window and a display (not illustrated) on a rear surface of the window, or may be a metal wire directly patterned on the rear surface of the window. Alternatively, the touch sensor may be formed integrally with the display. For example, the touch sensor may be disposed on a substrate of the display, or may be provided inside the display.

In this way, the display unit 151 may form a touch screen together with the touch sensor, and in this case, the touch screen may function as the user input unit (123, see FIG. 1A). In some cases, the touch screen may replace at least some of functions of a first manipulation unit 123a. Hereinafter, for the sake of explanation, the display unit (display module) for outputting the image and the touch sensor are collectively referred to as a touch screen 151.

The first audio output module 152a may be implemented as a receiver for transmitting a call sound to a user's ear and the second audio output module 152b may be implemented as a loud speaker for outputting various alarm sounds or multimedia playback sounds.

The window 151a of the display unit 151 may include a sound hole for emitting sounds generated from the first audio output module 152a. However, the present invention is not limited thereto, and the sounds may be released along an assembly gap between the structural bodies (for example, a gap between the window 151a and the front case 101). In this case, a hole independently formed to output audio sounds may not be seen or may otherwise be hidden in terms of appearance, thereby further simplifying the appearance of the electronic device 100.

The optical output module 154 may be configured to output light for indicating an event generation. Examples of such events may include a message reception, a call signal reception, a missed call, an alarm, a schedule alarm, an email reception, information reception through an application, and the like. When a user has checked a generated event, the controller 180 may control the optical output module 154 to stop the light output.

The first camera 121a may process image frames such as still or moving images obtained by the image sensor in a capture mode or a video call mode. The processed image frames can then be displayed on the display unit 151 or stored in the memory 170.

The first and second manipulation units 123a and 123b are examples of the user input unit 123, which may be manipulated by a user to provide input to the mobile terminal 100. The first and second manipulation units 123a and 123b may also be commonly referred to as a manipulating portion. The first and second manipulation units 123a and 123b may employ any method if it is a tactile manner allowing the user to perform manipulation with a tactile feeling such as touch, push, scroll or the like The first and second manipulation units 123a and 123b may also be manipulated through a proximity touch, a hovering touch, and the like, without a user's tactile feeling.

The drawings are illustrated on the basis that the first manipulation unit 123a is a touch key, but the present disclosure may not be necessarily limited to this. For example, the first manipulation unit 123a may be configured with a mechanical key, or a combination of a touch key and a push key.

The content received by the first and second manipulation units 123a and 123b may be set in various ways. For example, the first manipulation unit 123a may be used by the user to input a command such as menu, home key, cancel, search, or the like, and the second manipulation unit 123b may be used by the user to input a command, such as controlling a volume level being output from the first or second audio output module 152a or 152b, switching into a touch recognition mode of the display unit 151, or the like.

On the other hand, as another example of the user input unit 123, a rear input unit (not shown) may be disposed on the rear surface of the terminal body. The rear input unit may be manipulated by a user to input a command for controlling an operation of the electronic device 100. The content input may be set in various ways. For example, the rear input unit may be used by the user to input a command, such as power on/off, start, end, scroll or the like, controlling a volume level being output from the first or second audio output module 152a or 152b, switching into a touch recognition mode of the display unit 151, or the like. The rear input unit may be implemented into a form allowing a touch input, a push input or a combination thereof.

The rear input unit may be disposed to overlap the display unit 151 of the front surface in a thickness direction of the terminal body. As one example, the rear input unit may be disposed on an upper end portion of the rear surface of the terminal body such that a user can easily manipulate it using a forefinger when the user grabs the terminal body with one hand. However, the present disclosure may not be limited to this, and the position of the rear input unit may be changeable.

When the rear input unit is disposed on the rear surface of the terminal body, a new user interface may be implemented using the rear input unit. Also, the aforementioned touch screen or the rear input unit may substitute for at least part of functions of the first manipulation unit 123a located on the front surface of the terminal body. Accordingly, when the first manipulation unit 123a is not disposed on the front surface of the terminal body, the display unit 151 may be implemented to have a larger screen.

On the other hand, the electronic device 100 may include a finger scan sensor which scans a user's fingerprint. The controller may use fingerprint information sensed by the finger scan sensor as an authentication means. The finger scan sensor may be installed in the display unit 151 or the user input unit 123.

The microphone 122 may be formed to receive the user's voice, other sounds, and the like. The microphone 122 may be provided at a plurality of places, and configured to receive stereo sounds.

The interface unit 160 may serve as a path allowing the electronic device 100 to interface with external devices. For example, the interface unit 160 may be at least one of a connection terminal for connecting to another device (for example, an earphone, an external speaker, or the like), a port for near field communication (for example, an Infrared DaAssociation (IrDA) port, a Bluetooth port, a wireless LAN port, and the like), or a power supply terminal for supplying power to the electronic device 100. The interface unit 160 may be implemented in the form of a socket for accommodating an external card, such as Subscriber Identification Module (SIM), User Identity Module (UIM), or a memory card for information storage.

The second camera 121b may be further mounted to the rear surface of the terminal body. The second camera 121b may have an image capturing direction, which is substantially opposite to the direction of the first camera unit 121a.

The second camera 121b may include a plurality of lenses arranged along at least one line. The plurality of lenses may be arranged in a matrix form. The cameras may be referred to as an ‘array camera.’ When the second camera 121b is implemented as the array camera, images may be captured in various manners using the plurality of lenses and images with better qualities may be obtained.

The flash 124 may be disposed adjacent to the second camera 121b. When an image of a subject is captured with the camera 121b, the flash 124 may illuminate the subject.

The second audio output module 152b may further be disposed on the terminal body. The second audio output module 152b may implement stereophonic sound functions in conjunction with the first audio output module 152a, and may be also used for implementing a speaker phone mode for call communication.

At least one antenna for wireless communication may be disposed on the terminal body. The antenna may be embedded in the terminal body or formed in the case. For example, an antenna which configures a part of the broadcast receiving module 111 (see FIG. 1A) may be retractable into the terminal body. Alternatively, an antenna may be formed in a form of film to be attached onto an inner surface of the rear cover 300 or a case including a conductive material may serve as an antenna.

The terminal body is provided with a power supply unit 190 (see FIG. 1A) for supplying power to the electronic device 100. The power supply unit 190 may include a batter 191 which is mounted in the terminal body or detachably coupled to an outside of the terminal body.

The battery 191 may receive power via a power cable connected to the interface unit 160. Also, the battery 191 may be (re)chargeable in a wireless manner using a wireless charger. The wireless charging may be implemented by magnetic induction or electromagnetic resonance.

On the other hand, the drawing illustrates that the rear cover 300 is coupled to the rear case 102 for shielding the battery 191, so as to prevent separation of the battery 191 and protect the battery 191 from an external impact or foreign materials. When the battery 191 is detachable from the terminal body, the rear case 300 may be detachably coupled to the rear case 102.

An accessory for protecting an appearance or assisting or extending the functions of the electronic device 100 may further be provided on the electronic device 100. As one example of the accessory, a cover or pouch for covering or accommodating at least one surface of the electronic device 100 may be provided. The cover or pouch may cooperate with the display unit 151 to extend the function of the electronic device 100. Another example of the accessory may be a touch pen for assisting or extending a touch input onto a touch screen.

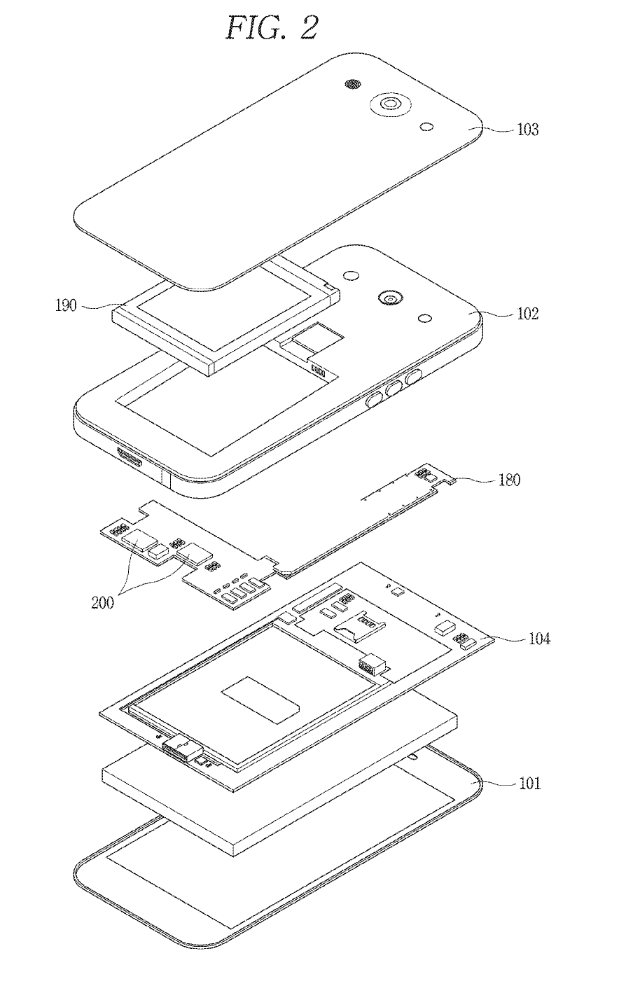

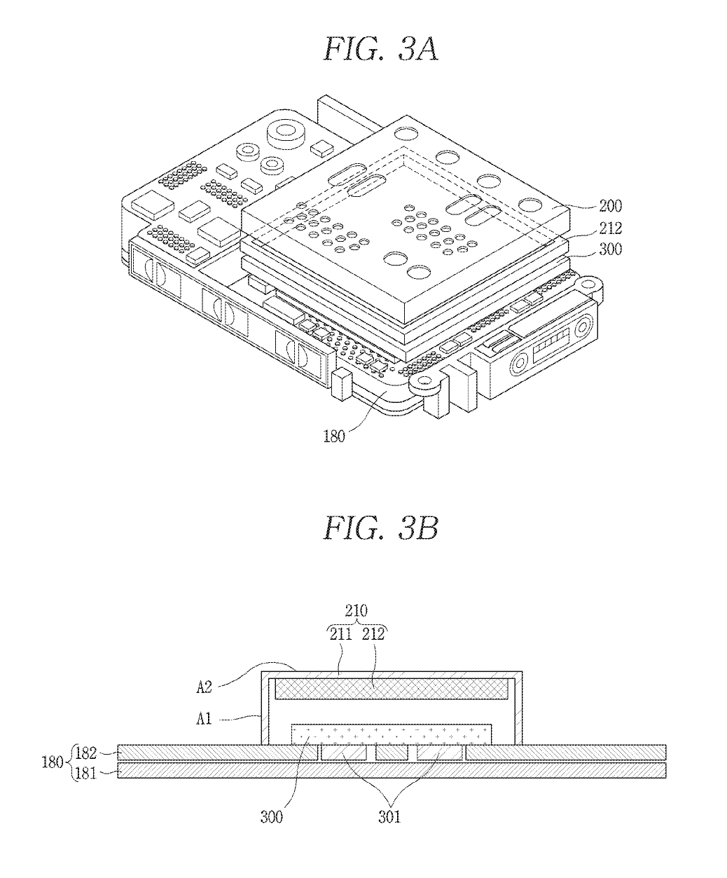

FIG. 2 is an exploded view of FIG. 10.

The electronic device 100 according to this embodiment has an inner space formed by the front case 101 and the rear case 102 and the rear cover 103 is fixed to the rear case 102. The battery 190 is mounted on one surface of the rear case 102. An accommodation space for accommodating the battery 190 is formed on one surface of the rear case 102. The rear cover 103 is mounted on the rear case 102 so as to cover the battery 190.

Inside the rear case 102, an inner frame 104 supporting a plurality of electronic components is disposed. The display unit 151 is supported on one surface of the inner frame 104 and the circuit board 180 is disposed on another surface of the inner frame 104.

A plurality of electronic components including a driving chip are disposed on the circuit board 180. The circuit board 180 may be formed so as not to overlap the battery 190. A shield can 200 is provided above the electronic component. The shield can 200 is provided to cover the electronic component. The shield can 200 is provided so as to individually cover each electronic component.

The shield can 200 is made of a metal and fixed to the circuit board 180. When a signal is applied to the electronic component, an electromagnetic wave is radiated. The electromagnetic wave is transmitted to the shield can 200 and is not emitted to outside. The electromagnetic wave transmitted to the shield can 200 is discharged to a ground region of the circuit board 180.

Hereinafter, the structure of the shield can according to various embodiments of the present invention will be described.

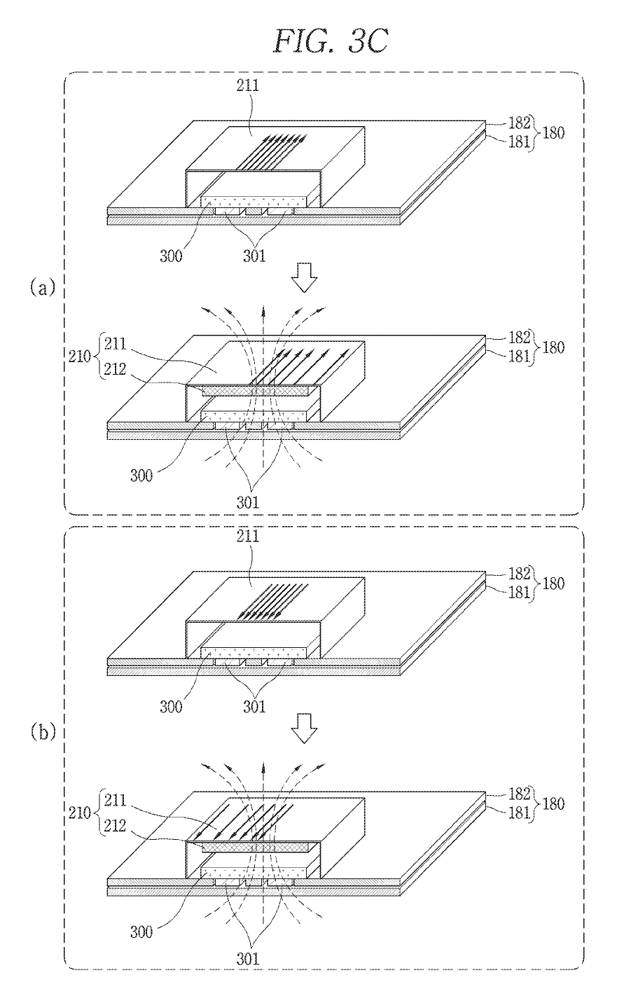

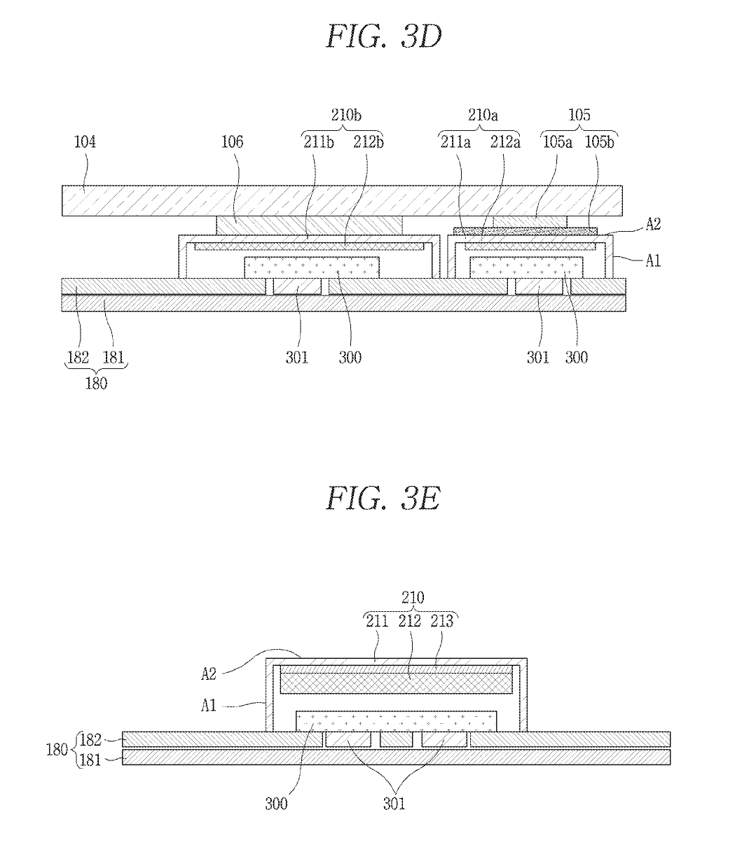

FIGS. 3A and 3B are views illustrating a structure of a first shield can.

An electronic component 300 is disposed on the circuit board 180. The first shield can 210 includes a base portion 211 fixed to the circuit board 180 and formed to cover the electronic component 300. That is, the first shield can 210 is fixed to the circuit board 180, and includes a first region A1 surrounding side portions of the electronic component 300 and a second region A2 extending from the first region A1 to face the circuit board 180. The second region A2 is spaced apart from the electronic component 300 at a preset interval.

The circuit board 180 includes a base layer 181 and a ground layer 182. The circuit board 180 includes a signal line 301 formed on the base layer 181 and electrically connected to the electronic component 300. The signal line 301 is connected to the electronic component 300 and transmits a control signal. The signal line 301 is disposed below the first shield can 210 together with the electronic component 300.

The base portion 211 of the first shield can 210 is mounted as a Surface Mount Type (SMT) on the ground layer 182. The first region A1 is in contact with the ground layer 182. Therefore, electromagnetic waves radiated from the electronic component 300 reach the second region A2 and discharged to the ground layer 182 through the first region A1.

The first shield can 210 further includes a magnet portion 212 attached to the second region A2 of the base portion 211. The magnet portion 212 may have a closed loop shape with a central region open, and may be formed along edges of the second region A2. The magnet portion 212 has a preset thickness and forms a space together with the electronic component 300. The magnet portion 212 is fixed to the metallic base portion 211 by a magnetic force.

Current flows in the first shield can 210 by a magnetic field generated in the electronic component 300. The magnet portion 212 may disperse the current flowing in the first shield can 210.

FIG. 3C is a conceptual view illustrating a characteristic in which current flowing in a shield can is dispersed by a magnet portion.

(a) of FIG. 3C shows a change in a flow of current according to an additionally-mounted state of the magnet portion when the current flows in a first direction. When the magnet portion 212 is not mounted on the base portion 211, the current flows in a manner of being concentrated onto a central region of the base portion 211.

A magnetic field is formed by the magnet portion 212 which is mounted on the base portion 211 and has the opening region. The magnetic field is formed through the opening region in a direction from inside to outside of the first shield can 210. According to the direction of the magnetic field and the flowing direction of the current, positive (+) charges move to right. Therefore, the current flows in a manner of being dispersed in a right direction on (a) of FIG. 3C.

(b) of FIG. 3C shows a change in a flow of current according to an additionally-mounted state of the magnet portion when the current flows in a second direction opposite to the first direction. When the magnet portion 212 is not mounted on the base portion 211, the current flows in a manner of being concentrated onto the central region of the base portion 211.

A magnetic field is formed by the magnet portion 212 which is mounted on the base portion 211 and has the opening region. The magnetic field is formed through the opening region in a direction from inside to outside of the first shield can 210. A force by which negative (-) charges move to right is generated along the direction of the magnetic field and the flowing direction of the current. Therefore, the current flows in a manner of being dispersed in a left direction on (b) of FIG. 3C. The flowing direction of the current and the direction of the magnetic field are perpendicular to each other. That is, the signal line 301 is disposed on the circuit board 180.

The current distribution is changed by a force applied in a direction orthogonal to the flowing charges (current). Accordingly, when the applied current is AC-sinusoidal wave, the direction in which the current is dispersed is alternately switched.

According to the present invention, the current flowing along the shield can be dispersed to outside. Therefore, even when the shield can and the electronic component have a narrow distance therebetween and when an electronic component generating high frequency waves having a straight-running property is arranged, an induced current can efficiently flow to the ground.

FIG. 3D is a conceptual view illustrating a structure in which a heat dissipating structure is arranged in a shield can in accordance with one embodiment.

A plurality of electronic components 300 are disposed on the circuit board 180 and signal lines 301 are connected to the base layer 181 of the circuit board 180 to transmit control signals to the electronic components 300, respectively.

The first and second shield cans 210a and 210b are disposed on the plurality of electronic components 300, respectively. First and second base portions 211a and 211b of the first and second shield cans 210a and 210b have inner spaces for covering the plurality of electronic components 300, respectively, and are fixed to the ground layer 182 in a contact state.

As illustrated in FIG. 3D, first and second magnet portions 212a and 212b are fixed to inner surfaces of the first and second base portions 211a and 211 b facing the electronic components 300, respectively. Each of the first and second base portions 211a and 211b includes a first region A1 brought into contact with the ground layer 182 and a second region A2 facing the circuit board 180. Each of the first and second magnet portions 212a and 212b is disposed on the inner surface of the second region A2 of each of the first and second base portions 211a and 211b.

The electronic device 100 according to this embodiment includes a heat dissipating structure 105 for dissipating heat generated therein. The heat dissipating structure 105 includes a heat pipe 105a and a thermal pad 105b.

The thermal pad 105b and the heat pipe 105a may be disposed on an outer surface of the first base portion 211a. For example, the thermal pad 105b and the heat pipe 105a may be disposed on the second region A2 of the first base portion 211a.

The electronic device 100 includes an inner frame 104 that is disposed therein and supports the plurality of electronic components, and the electronic components 300 are arranged between the circuit board 180 and the inner frame 104. The inner frame 104 may be made of a metal material.

The thermal pad 105b and the heat pipe 105a are disposed between the inner frame 104 and the first base portion 211a. Specifically, the thermal pad 105b is attached to the second region A2 of the first base portion 211a, and the heat pipe 105a is disposed on the thermal pad 105b. Heat generated in the electronic component 300 is dispersed through the heat pipe 105a. Although not specifically illustrated, the heat pipe 105a may be brought into contact with another structure such as a case for discharging heat.

Most of the heat emitted from the electronic component 300 (part of the heat is dispersed by convection and radiation) is dispersed by being conducted to the first shield can 210a. The heat conducted to the first shield can 210a is dispersed through the thermal pad 105b and discharged to outside through the heat pipe 105a which is brought into contact with the inner frame 104.

The heat pipe 105a and the thermal pad 105b may be attached to the first base portion 211a by adhesive members.

On the other hand, a gasket 106 may be mounted on the second base portion 211b of the second shield can 210b. The gasket 106 is made of a metal material and connected to the inner frame 104 so that the shield can 210 can be grounded to the inner frame 104.

Since the heat dissipating structure is mounted on the base portion of the shield can even when the magnet portion is included, heat generated by the electronic component can be efficiently dissipated.

FIG. 3E is a conceptual view illustrating a shield can having an adhesive member for attaching a magnet portion.

Referring to FIG. 3E, the first shield can 210 includes a base portion 211, a magnet portion 212, and an adhesive member 213 for attaching the magnet portion 212 and the base portion 211 to each other. The other components except for the adhesive member 213 are substantially the same as those of FIG. 3B. Therefore, the same reference numerals are assigned to the same components, and redundant description is omitted.

The adhesive member 213 is attached to an inner surface of the second area A2 of the base portion 211 of the first shield can 210, such that the magnet portion 212 is fixed to the first shield can 210.

This may prevent the magnet portion 212 from being separated from the base portion 211.

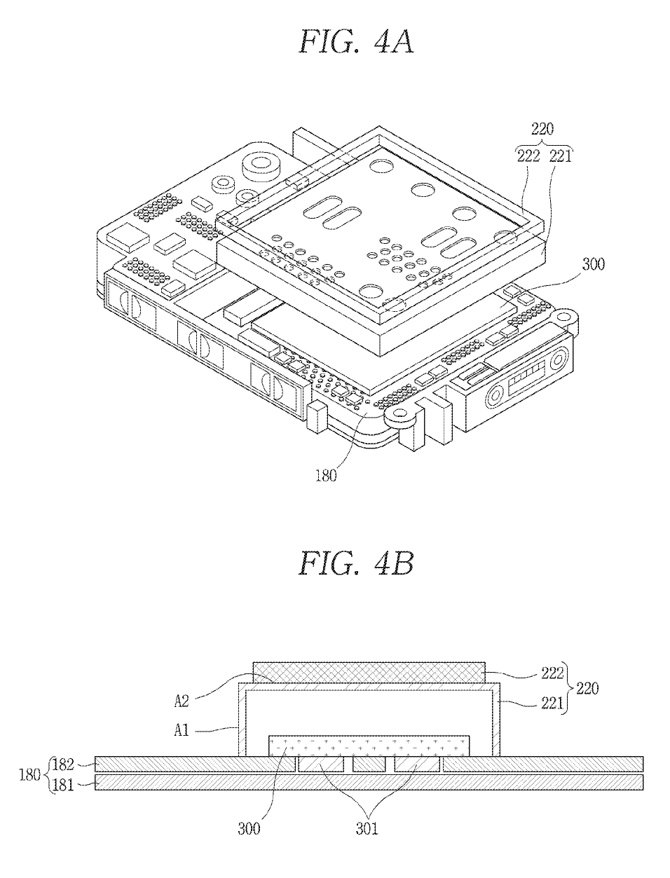

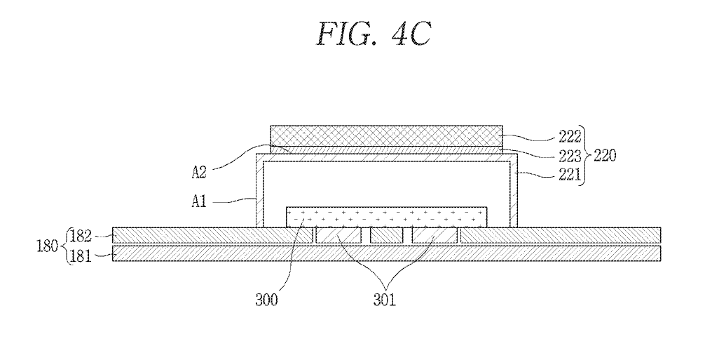

FIGS. 4A and 4B are conceptual views illustrating a second shield can in accordance with another embodiment of the present invention.

The second shield can 220 according to this embodiment includes a base portion 221 and a magnet portion 222. The base portion 221 includes a first region A1 brought into contact with the base layer 181 of the circuit board 180 and a second region A2 extending from the first region A1 and covering the electronic components 300.

The magnet portion 222 is disposed in the second region A2 and has a closed loop shape with a central region open. The magnet portion 222 is formed along edges of the second region A2. The magnet portion 222 is formed on an outer surface of the second region A2. The magnet portion 222 is fixed to the metallic base portion 221 by a magnetic force.

A magnetic field is formed by the shape of the magnet portion 222 from inside to outside of the base portion 221, and current flowing in the central region of the shield can 221 may be diffused by the magnetic field. Accordingly, the current induced in the shield can 221 may be uniformly distributed and flow toward the ground layer 182 along the first and second regions A1 and A2 of the shield can 221.

FIG. 4C is a conceptual view illustrating a structure in which a magnet portion is fixed by an adhesive member.

Components of the second shield can 220 according to FIG. 4C are substantially the same as the components of FIG. 4B except for an adhesive member 223.

The adhesive member 223 is provided on an outer surface of the second region A2 of the second shield can 220 and the magnet portion 222 is attached by the adhesive member 223. The adhesive member 223 may be formed to have the same cross-section as that of the magnet portion 222.

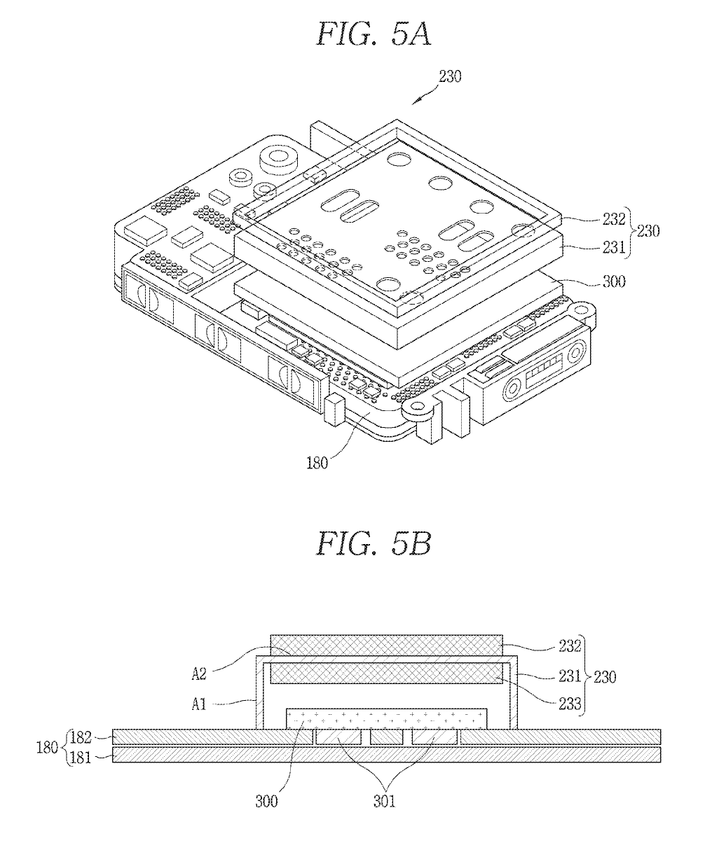

FIGS. 5A and 5B are conceptual views illustrating a structure of a third shield can in accordance with another embodiment of the present invention.

Referring to FIGS. 5A and 5B, the third shield can 230 includes a base portion 231, a first magnet portion 232, and a second magnet portion 233. The base portion 231 includes a first region A1 brought into contact with the ground layer 182 of the circuit board 180 to form side surfaces of the base portion 231, and a second region A2 extending from the first region A1 and facing the circuit board 180 to cover the electronic component 300.

The first and second magnet portions 232 and 233 are disposed on the second region A2. The first and second magnet portions 232 and 233 are fixed to outer and inner surfaces of the second region A2, respectively. The first and second magnet portions 232 and 233 disposed with the second region A2 interposed therebetween are fixed to the base portion 231 by an attractive force applied therebetween, without an additional adhesive member.

The first and second magnet portions 232 and 233 may have a closed loop shape and have substantially the same shape. The first and second magnet portions 232 and 233 are disposed to overlap each other with the second region A2 interposed therebetween.

According to this embodiment, the pair of magnet portions can be stably fixed to the base portion 231 without an additional adhesive member.

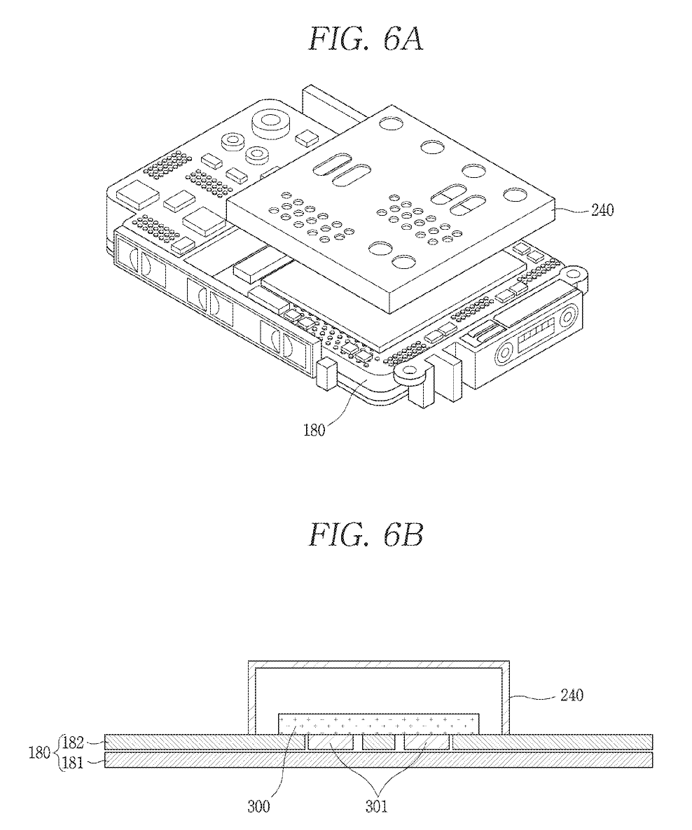

FIGS. 6A and 6B are conceptual views illustrating a fourth shield can in accordance with another embodiment of the present invention.

The fourth shield can 240 according to this embodiment is implemented as a magnetized metallic base portion. The fourth shield can 240 does not include an additional magnet portion. The base portion is made of a ferromagnetic material that can be magnetized. The magnetized fourth shield can 240 forms a magnetic field in a direction from inside to outside of the shield can. This may result in dispersing a current flowing along one region of the shield can.

Here, the ferromagnetic material is a material having a large dipole moment, and is made of a material whose electron spin moment is not completely canceled. It is a property of magnetic moments of electrons which fail to be paired in the atom, and the dipole moments in a predetermined region are arranged parallel to each other by forces applied between atoms. For example, the ferromagnetic material may be made of iron, nickel cobalt, or the like.

According to this embodiment, a magnetic field can be formed without an additional magnet portion.

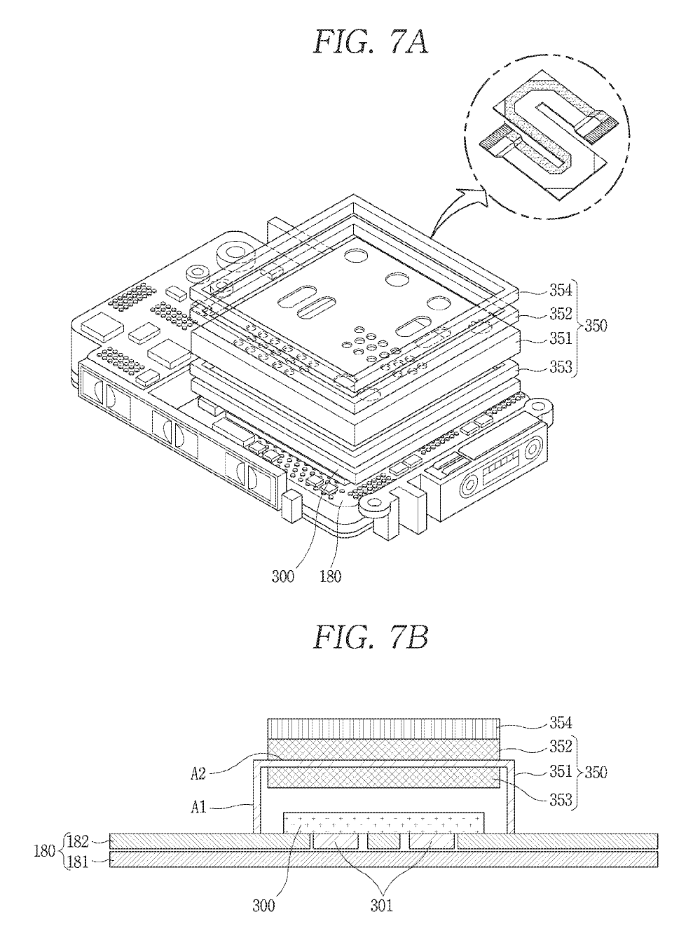

FIGS. 7A and 7B are conceptual views illustrating a fifth shield can in accordance with one embodiment of the present invention.

The fifth shield can 350 includes a base portion 351, and first and second magnet portions 352 and 353. The fifth shield can 350 is made of a ferromagnetic material which may have magnetism.

The fifth shield can 350 includes a first region A1 brought into contact with the ground layer 182 of the circuit board 180, and a second region A2 covering the circuit board 180. The first and second magnet portions 352 and 353 are disposed to face each other with the second region A2 interposed therebetween. The first and second magnet portions 352 and 353 are fixed to the base portion 351 by an attractive force therebetween. That is, the first and second magnet portions 352 and 353 have substantially the same shape and are arranged at positions corresponding to each other.

A flexible circuit board 354 may be disposed on the fifth shield can 350. The flexible circuit board 354 may be disposed on the first magnet portion 352. The flexible circuit board 354 may correspond to a component (such as a line and an antenna) of an electronic component disposed therearound.

The fifth shield can 350 includes the base portion 351 made of a ferromagnetic material, and the first and second magnet portions 352 and 353, thereby minimizing generation of eddy currents. This may result in preventing performance deterioration occurring when the flexible circuit board 354 is disposed in a peripheral region of the fifth shield can 350.

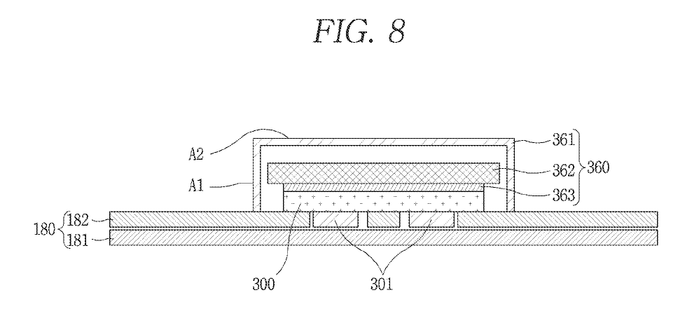

FIG. 8 is a conceptual view illustrating a structure of a sixth shield can in accordance with another embodiment of the present invention.

Referring to FIG. 8, the sixth shield can 360 includes a base portion 361, a magnet portion 362, and an adhesive member 363. The base portion 361 has a first region A1 forming side surfaces and brought into contact with the ground layer 182, and a second region A2 extending from the first region A1 and formed to face the circuit board 181.

The electronic component 300 is disposed inside the base portion 361 and the magnet portion 362 is attached to the electronic component 300 by the adhesive member 363. The magnet portion 362 is formed in a closed loop shape with a central region open. A magnetic field is formed by the magnet portion 362 having the closed loop shape, in a direction penetrating through the opening region, namely, from the electronic component to the second region A2.

That is, the magnet portion 362 is disposed in a specific region of the sixth shield can 360 so that the magnetic field is formed in a specific direction.

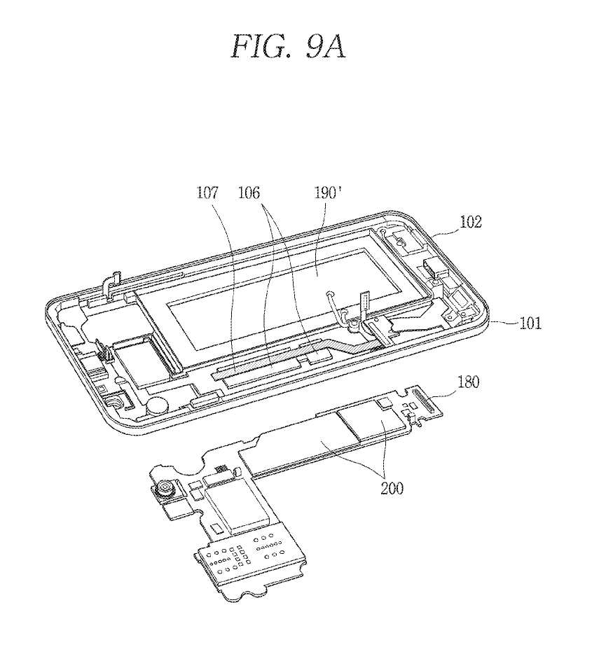

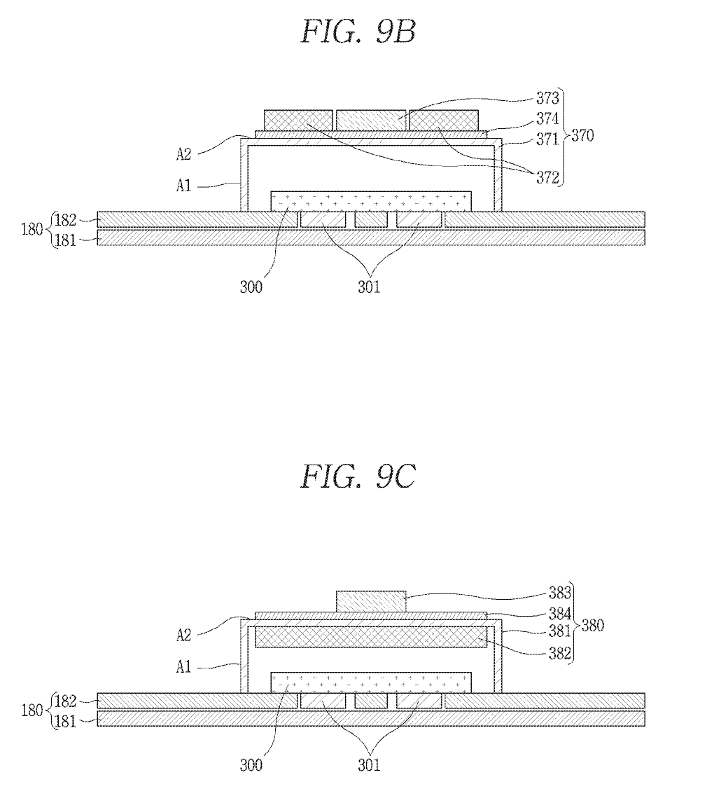

FIGS. 9A to 9C are conceptual views illustrating an arrangement structure of a heat dissipating structure and a shield can.

Referring to FIG. 9A, the front case 101 and the rear case 102 form an inner space of the electronic device. One region of the inner space is formed as an accommodation space 190′ for mounting the battery, and the circuit board 180 is mounted in a remaining region of the inner space except for the accommodation space 190′.

A thermal pad 106 and a heat pipe 107 are provided on one region of the rear case 102 (or the inner frame disposed inside the rear case 102). The thermal pad 106 may be provided on a specific electronic component. The thermal pad 106 may have a shape elongated in one direction, but is not limited thereto. Heat transferred to the thermal pad 106 is discharged to outside by the heat pipe 107. The heat pipe 107 may be brought into contact with the inner frame and/or the case to dissipate the heat.

An electronic component is disposed on one region of the circuit board 180, and covered by the shield can 200. The circuit board 180 on which the electronic component and the shield can 200 are disposed is mounted on a region where the thermal pad 106 and the heat pipe 107 are disposed. That is, the shield can 200 and the heat pipe 107 may be brought into contact with each other. Accordingly, heat generated by the electronic component 300 can be dispersed to the heat pipe 107 through the shield can 200.

Referring to FIG. 9B, a seventh shield can 370 according to this embodiment includes a base portion 371, magnet portions 372, a heat pipe 373, and a thermal pad 374. The base portion 371 includes a first region A1 brought into contact with the ground layer 182 and forming side surfaces, and a second s region A2 extending from the first region A1 and formed to face the circuit board 180.

The magnet portions 372, the heat pipe 373, and the thermal pads 374 are disposed on an outer surface of the second region A2. The thermal pads 374 are provided on the second region A2 and the magnet portion 372 and the heat pipe 373 are disposed on the thermal pad 374.

The heat pipe 373 is brought into contact directly with the thermal pad 374. The magnet portions 372 are not disposed between the thermal pad 374 and the heat pipe 373. The magnet portion 372 may include an opening region corresponding to a position where the thermal pad 374 is disposed.

An eighth shield can 380 according to FIG. 9C includes a base portion 381, a magnet portion 382, a heat pipe 383 and a thermal pad 384.

The base portion 381 includes a first region A1 brought into contact with the ground layer 182 and forming side surfaces, and a second region A2 extending from the first region A1 and formed to face the circuit board 180.

The magnet portion 382 is disposed on an inner surface of the second region A2. The magnet portion 382 may be fixed to the base portion 381 made of a metal by a magnetic force, or may be fixed to the base portion 381 by an additional adhesive member.

The thermal pad 384 is formed on an outer surface of the second region A2 of the base portion 831. The heat pipe 383 is disposed on the thermal pad 384. Since the thermal pad 384 provided on the second region A2 is in contact with the larger second region A2, a heat dissipating function can be improved.

FIG. 10 is a conceptual view illustrating a structure of a ninth shield can in accordance with another embodiment.

The ninth shield can 390 includes a base portion 391 only having a side surface portion and including an opening region, a cover portion 392 formed to cover the opening region, and a magnet portion 393 disposed on the cover portion 392. The cover portion 392 is inserted into the opening region to form an inner space of the ninth shield can 390.

The magnet portion 393 may be disposed on an inner surface or an outer surface of the cover portion 392. When the magnet portion 393 is disposed on the inner surface of the cover portion 393, the size of the magnet portion 393 becomes smaller than or substantially the same as that of the opening region.

FIG. 11 is a conceptual view illustrating a structure of a shield can implemented by an inner frame in accordance with another embodiment.

The inner frame 104 is disposed inside the body to support the electronic components. The inner frame 104 includes a support portion 104a with which the base layer 181 of the circuit board 180 is brought into contact, and a side wall portion 104b formed to face the circuit board 180. The electronic components 300 are disposed in an inner space formed by the inner frame 104 and the circuit board 180.

Signal lines 301 for transmitting signals to the electronic components 300 are also provided in one region of the base layer 181 corresponding to the inner space.

The magnet portion 400 according to this embodiment may be disposed on an inner surface or an outer surface of the side wall portion 104b facing the electronic components. Although not illustrated, the structure of the shield can according to this embodiment includes a plurality of magnet portions, or the magnet portion may be attached to the inner frame 104 by an adhesive member.

The inner frame 104 may alternatively be made of a magnetized ferromagnetic material. In this case, the magnet portion 400 does not have to be disposed.

The present invention can be implemented as computer-readable codes in a program-recorded medium. The computer-readable medium may include all types of recording devices each storing data readable by a computer system. Examples of such computer-readable media may include hard disk drive (HDD), solid state disk (SSD), silicon disk drive (SDD), ROM, RAM, CD-ROM, magnetic tape, floppy disk, optical data storage element and the like. Also, the computer-readable medium may also be implemented as a format of carrier wave (e.g., transmission via an Internet). The computer may include the controller 180 of the terminal. Therefore, it should also be understood that the above-described embodiments are not limited by any of the details of the foregoing description, unless otherwise specified, but rather should be construed broadly within its scope as defined in the appended claims, and therefore all changes and modifications that fall within the metes and bounds of the claims, or equivalents of such metes and bounds are therefore intended to be embraced by the appended claims.

What is claimed is:

1. An electronic device comprising:
a body including an inner frame;
a circuit board disposed inside the body to transmit a signal;
an electronic component disposed on the circuit board; and
a shield can disposed between the circuit board and the inner frame, and covering the electronic component such that a current induced by an electromagnetic field from the electronic component flows toward the circuit board,
wherein the shield can comprises:
a base portion including a first region fixed to the circuit board, and a second region covering the electronic component; and
at least one magnet portion overlapping the second region of the base portion, and producing a magnetic field in a direction leading from an interior of the base portion to an exterior of the base portion to disperse a flow of the current on the base portion.

2. The electronic device of claim 1, wherein the at least one magnet portion has a shape of a closed loop with a central opening, and
wherein the direction of the produced magnetic field and a direction of the flow of the current intersect each other.

3. The electronic device of claim 2, wherein the at least one magnet portion is disposed on an inner surface or an outer surface of the second region of the base portion.

4. The electronic device of claim 3, further comprising an adhesive member adhering the at least one magnet portion and the base portion to each other.

5. The electronic device of claim 2, wherein the at least one magnet portion comprises a first magnet portion and a second magnet portion disposed, respectively, on an inner surface and an outer surface of the second region of the base portion, and
wherein the first and second magnet portions are disposed to overlap each other so as to be fixed to the base portion by an attractive force.

6. The electronic device of claim 5, further comprising a flexible circuit board disposed on the second magnet portion to perform a specific function.

7. The electronic device of claim 1, wherein the at least one magnet portion is disposed in an interior space formed by the base portion, and
wherein the at least one magnet portion is attached to the electronic component by an adhesive member.

8. The electronic device of claim 1, wherein the circuit board comprises a base layer, a ground layer fixed to the base layer, and a signal line on the base layer to transmit the signal to the electronic component.

9. The electronic device of claim 1, further comprising a thermal pad in contact with an outer surface of the second region of the base portion to transfer heat, and
wherein the at least one magnet portion is provided on the thermal pad or on an inner surface of the second region.

10. The electronic device of claim 9, further comprising a heat pipe in contact with the thermal pad to dissipate heat.

11. The electronic device of claim 10, wherein the at least one magnet portion has an opening through which the heat pipe extends, and wherein the at least one magnet portion is provided on the thermal pad.

12. The electronic device of claim 1, further comprising a thermal pad and a heat pipe disposed on the inner frame, and
wherein a portion of the shield can is disposed on the thermal pad and the heat pipe.

13. The electronic device of claim 1, wherein the shield can is made of a magnetized ferromagnetic material.

14. The electronic device of claim 1, wherein the inner frame comprises a side wall portion fixed to the circuit board, and a support portion covering the electronic component, and
wherein the at least one magnet portion is disposed on the support portion of the inner frame.
